(19) United States
(12) Patent Application Publication
(10) Pub. No.: US 2023/0262971 A1
(43) Pub. Date: Aug. 17, 2023

(54) SEMICONDUCTOR STORAGE DEVICE

(71) Applicant: Kioxia Corporation, Tokyo (JP)

(72) Inventors: Yukinori KOYAMA, Yokkaichi Mie (JP); Takayuki ISHIKAWA, Yokkaichi Mie (JP); Shinji NAKADA, Yokkaichi Mie (JP)

(73) Assignee: Kioxia Corporation, Tokyo (JP)

(21) Appl. No.: 17/896,900

(22) Filed: Aug. 26, 2022

(30) Foreign Application Priority Data
Feb. 15, 2022 (JP) 2022-021429

(51) Int. Cl. H01L 27/11556; H01L 27/11519; H01L 27/11565; H01L 27/11582

(52) U.S. Cl. CPC H01L 27/11556; H01L 27/11519; H01L 27/11565; H01L 27/11582

(57) ABSTRACT

A semiconductor storage device includes a substrate; a plurality of first conductive layers arranged in a first direction intersecting the substrate and extending in a second direction intersecting the first direction; a semiconductor layer extending in the first direction and disposed adjacent the plurality of first conductive layers; and a plurality of first charge storage layers arranged in the first direction, each of the first charge storage layers provided between a corresponding one of the plurality of first conductive layers and the semiconductor layer. Each of the first charge storage layers includes silicon (Si) and at least one of germanium (Ge), tin (Sn), magnesium (Mg), or carbon (C).

### CROSS-REFERENCE TO RELATED APPLICATION(S)

This application is based upon and claims the benefit of priority from Japanese Patent Application No. 2022-021429, filed Feb. 15, 2022, the entire contents of which are incorporated herein by reference.

### FIELD

Embodiments described herein relate generally to a semiconductor storage device.

### BACKGROUND

In general, a semiconductor storage device includes a substrate, a plurality of conductive layers lining up in a first direction intersecting the substrate and extending in a second direction intersecting the first direction, a semiconductor layer extending in the first direction and facing the plurality of conductive layers, and a plurality of charge storage layers provided between the plurality of conductive layers and the semiconductor layer and lining up in the first direction.

### DESCRIPTION OF THE DRAWINGS

FIG. 1 is a schematic equivalent circuit diagram of a semiconductor storage device according to a first embodiment.

FIG. 2 is a schematic plan view of the semiconductor storage device.

FIG. 3 is a schematic plan view of the semiconductor storage device.

FIG. 4 is a schematic cross-sectional view of the semiconductor storage device.

FIG. 5 is a schematic plan view of the semiconductor storage device.

FIG. 6 is a schematic cross-sectional view of the semiconductor storage device.

FIG. 7 is a schematic band diagram illustrating a writing operation of the semiconductor storage device.

FIG. 8 is a schematic graph illustrating a floating gate of the semiconductor storage device.

FIG. 9 is a schematic band diagram illustrating a writing operation according to a comparative example.

FIG. 10 is a schematic band diagram illustrating the writing operation of the semiconductor storage device according to the first embodiment.

FIG. 11 is a schematic plan view illustrating a manufacturing method for the semiconductor storage device.

FIG. 12 is a schematic cross-sectional view illustrating the manufacturing method.

FIG. 13 is a schematic plan view illustrating the manufacturing method.

FIG. 14 is a schematic cross-sectional view illustrating the manufacturing method.

FIG. 15 is a schematic plan view illustrating the manufacturing method.

FIG. 16 is a schematic cross-sectional view illustrating the manufacturing method.

FIG. 17 is a schematic plan view illustrating the manufacturing method.

FIG. 18 is a schematic cross-sectional view illustrating the manufacturing method.

FIG. 19 is a schematic plan view illustrating the manufacturing method.

FIG. 20 is a schematic cross-sectional view illustrating the manufacturing method.

FIG. 21 is a schematic plan view illustrating the manufacturing method.

FIG. 22 is a schematic cross-sectional view illustrating the manufacturing method.

FIG. 23 is a schematic plan view illustrating the manufacturing method.

FIG. 24 is a schematic cross-sectional view illustrating the manufacturing method.

FIG. 25 is a schematic plan view illustrating the manufacturing method.

FIG. 26 is a schematic cross-sectional view illustrating the manufacturing method.

FIG. 27 is a schematic plan view illustrating the manufacturing method.

FIG. 28 is a schematic cross-sectional view illustrating the manufacturing method.

FIG. 29 is a schematic cross-sectional view illustrating the manufacturing method.

FIG. 30 is a schematic cross-sectional view illustrating the manufacturing method.

FIG. 31 is a schematic cross-sectional view illustrating the manufacturing method.

FIG. 32 is a schematic cross-sectional view illustrating the manufacturing method.

FIG. 33 is a schematic cross-sectional view illustrating the manufacturing method.

FIG. 34 is a schematic cross-sectional view illustrating the manufacturing method.

FIG. 35 is a schematic cross-sectional view illustrating the manufacturing method.

FIG. 36 is a schematic cross-sectional view illustrating the manufacturing method.

FIG. 37 is a schematic cross-sectional view illustrating the manufacturing method.

### DETAILED DESCRIPTION

Embodiments provide a semiconductor storage device capable of high integration.

In general, according to one embodiment, a semiconductor storage device includes a substrate; a plurality of first conductive layers arranged in a first direction intersecting the substrate and extending in a second direction intersecting the first direction; a semiconductor layer extending in the first direction and disposed adjacent the plurality of first conductive layers; and a plurality of first charge storage layers arranged in the first direction, each of the first charge storage layers provided between a corresponding one of the plurality of first conductive layers and the semiconductor layer. Each of the first charge storage layers includes silicon (Si) and at least one of germanium (Ge), tin (Sn), magnesium (Mg), or carbon (C).

A semiconductor storage device according to an embodiment will be described hereinafter in detail with reference to the drawings. The following embodiments are merely examples, and are not intended to limit the present disclosure. The following drawings are schematic, and some components or the like may be omitted for convenience of description. Further, portions common to the plurality of embodiments are denoted by the same reference numerals, and a description thereof may be omitted.

In the present specification, the “semiconductor storage device” may mean a memory die, or may mean a memory system including a control die, such as a memory chip, a memory card, or a solid state drive (SSD). Further, the “semiconductor storage device” may mean a configuration including a host computer, such as a smartphone, a tablet terminal, or a personal computer.

Further, in the present specification, a case where a first configuration is “electrically connected to” a second configuration may mean that the first configuration is directly connected to the second configuration or the first configuration is connected to the second configuration via a wiring, a semiconductor member, a transistor, or the like. For example, when three transistors are connected in series, a first transistor is “electrically connected” to a third transistor even if a second transistor is in an OFF state.

Furthermore, in the present specification, a predetermined direction parallel to an upper surface of a substrate is referred to as an “X direction”, a direction parallel to the upper surface of the substrate and perpendicular to the X direction is referred to as a “Y direction”, and a direction perpendicular to the upper surface of the substrate is referred to as a “Z direction”.

Moreover, in the present specification, a direction along a predetermined surface may be referred to as a “first direction”, a direction along this predetermined surface and crossing the first direction may be referred to as a “second direction”, and a direction crossing this predetermined surface may be referred to as a “third direction”. The first direction, the second direction, and the third direction may correspond to or not correspond to the X direction, the Y direction, and the Z direction.

Further, in the present specification, expressions like “upper” and “lower” are based on the substrate. For example, a direction of separating from the substrate along the Z direction is referred to as an upper direction and a direction of approaching the substrate along the Z direction is referred to as a lower direction. Moreover, it is assumed that a lower surface or a lower end for a certain configuration refers to a surface or an end portion of the configuration closer to the substrate, and that an upper surface or an upper end for the certain configuration refers to a surface or an end portion of the configuration opposite to the substrate. Further, a surface intersecting the X direction or the Y direction is referred to as a side surface or the like.

### First Embodiment

Circuit Configuration of Semiconductor Storage Device

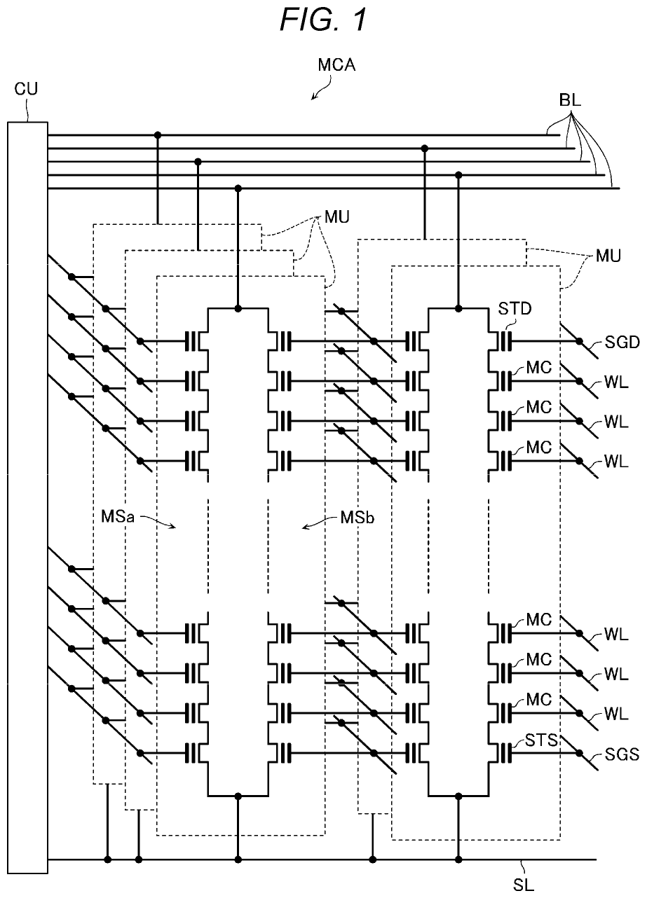

FIG. 1 is a schematic equivalent circuit diagram of a semiconductor storage device according to a first embodiment.

The semiconductor storage device according to the embodiment includes a memory cell array MCA and a control unit CU that controls the memory cell array MCA.

The memory cell array MCA includes a plurality of memory units MU. Each of the plurality of memory units MU includes two electrically independent memory strings MSa and MSb. One end of each of these memory strings MSa and MSb is connected to a drain side select transistor STD, and is connected to a common bit line BL via the drain side select transistor STD. The other end of each of the memory strings MSa and MSb is connected to a source side select transistor STS, and is connected to a common source line SL via the source side select transistor STS.

Each of the memory strings MSa and MSb includes a plurality of memory cells MC connected in series. The memory cells MC are field effect transistors including a semiconductor layer, a gate insulating layer, and a gate electrode. The semiconductor layer functions as a channel region. The gate insulating layer includes a charge storage unit that can store data. A threshold voltage of the memory cell MC changes according to a charge amount in the charge storage unit. The gate electrode is a part of a word line WL.

The select transistor (STD, STS) is a field effect transistor including a semiconductor layer, a gate insulating layer, and a gate electrode. The semiconductor layer functions as a channel region. The gate electrode of the drain side select transistor STD is a part of a drain side select gate line SGD. The gate electrode of the source side select transistor STS is a part of a source side select gate line SGS.

The control unit CU generates, for example, voltages required for a reading operation, a writing operation, and an erasing operation, and supplies the voltages to the bit line BL, the source line SL, the word line WL, and the select gate line (SGD, SGS). The control unit CU may include, for example, a plurality of transistors and wiring provided on the same substrate as the memory cell array MCA or may include a plurality of transistors and wiring provided on a substrate different from the substrate of the memory cell array MCA.

Structure of Semiconductor Storage Device

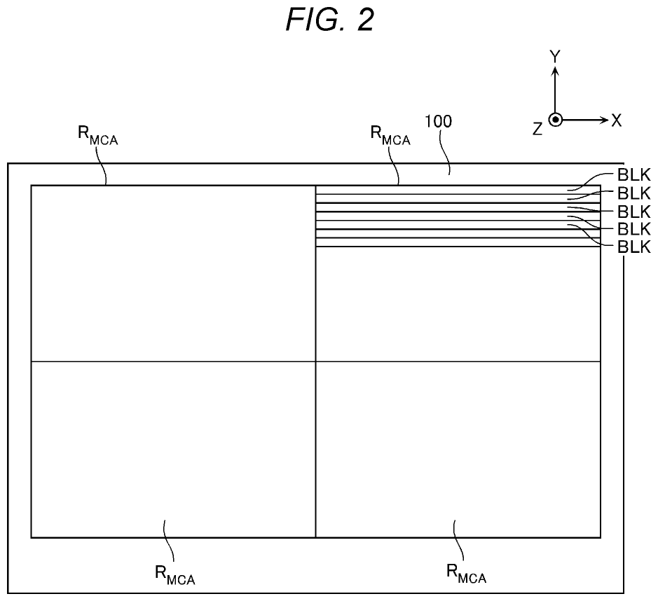

FIG. 2 is a schematic plan view illustrating a configuration example of the semiconductor storage device according to the embodiment.

The semiconductor storage device according to the embodiment includes a semiconductor substrate 100. In the illustrated example, the semiconductor substrate 100 is provided with four memory cell array regions RMCA lining up in an X direction and a Y direction. Each memory cell array region RMCA is provided with a plurality of memory blocks BLK lining up in the Y direction. Each memory block BLK extends in the X direction.

The semiconductor substrate 100 (FIG. 2) is, for example, a semiconductor substrate such as single crystal silicon (Si). The semiconductor substrate 100 contains, for example, a double-well structure including an n-type impurity layer on the upper surface of the semiconductor substrate and further including a p-type impurity layer in the n-type impurity layer. A surface of the semiconductor substrate 100 may be provided with, for example, transistors, wirings, and the like that form at least a part of the control unit CU (FIG. 1).

Configuration of Memory Cell Array Region R_{MCA}

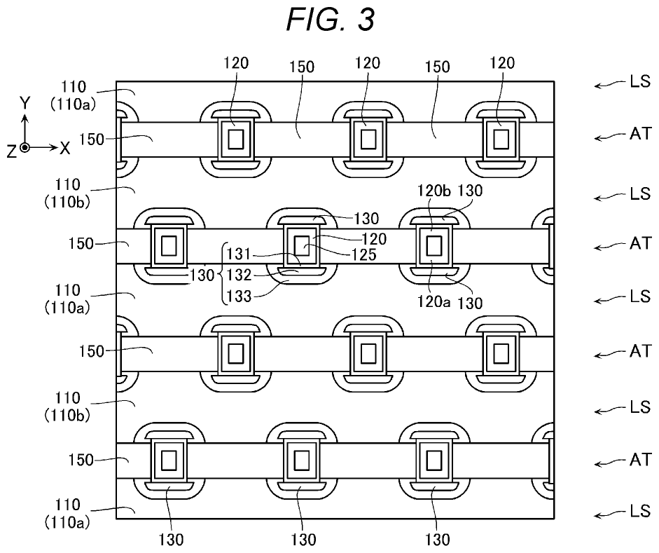

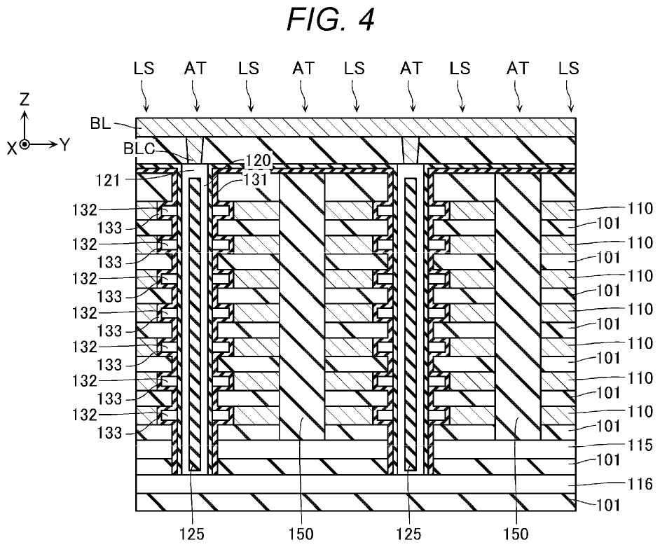

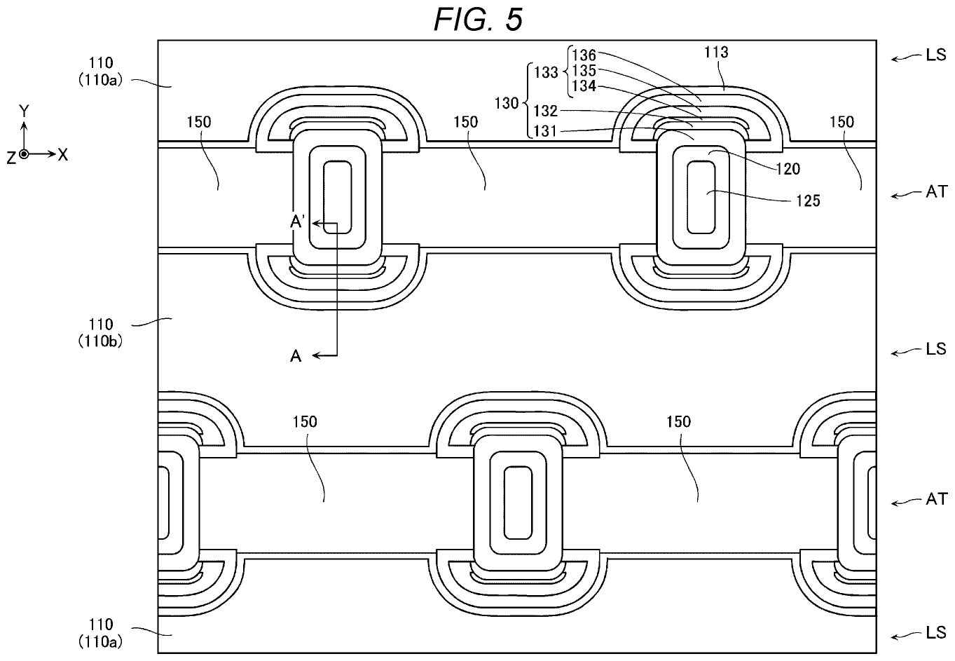

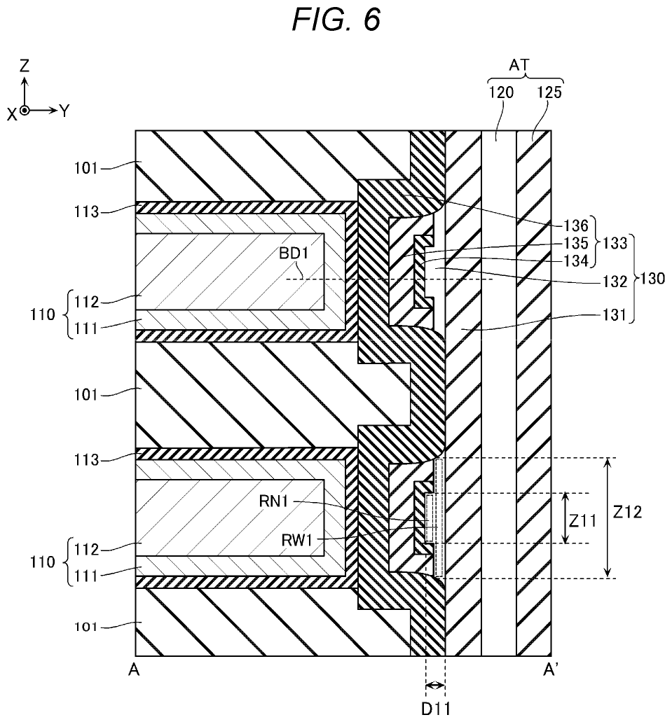

FIG. 3 is a schematic XY cross-sectional view illustrating a part of a configuration of the memory cell array region R_{MCA}. FIG. 4 is a schematic YZ cross-sectional view illustrating a part of a configuration of the memory cell array region R_{MCA}. FIG. 5 is a schematic enlarged view illustrating a part of the configuration in FIG. 3. FIG. 6 is a schematic cross-sectional view when the configuration illustrating in FIG. 5 is cut along an A-A′ line and viewed along a direction of arrows.

The semiconductor storage device according to the embodiment includes, for example, a plurality of stacked body structures LS and a plurality of trench structures AT, as illustrated in FIGS. 3 and 4. The plurality of stacked body structures LS line up in the Y direction on the semiconductor substrate 100. The plurality of trench structures AT are provided between the plurality of stacked body structures LS, respectively.

As illustrated in FIG. 4, for example, the stacked body structure LS includes a plurality of conductive layers 110 and a semiconductor layer 115 and a semiconductor layer 116 provided below the conductive layers 110. The plurality of conductive layers 110, the semiconductor layer 115, and the semiconductor layer 116 are stacked in the Z direction via insulating layers 101 such as silicon oxide (SiO₂), respectively.

The trench structure AT includes a plurality of semiconductor layers 120, for example, as illustrated in FIG. 3. The plurality of semiconductor layers 120 extend in the Z direction and line up in the X direction via an insulating layer 150 such as silicon oxide (SiO₂). A gate insulating layer 130 is provided between the conductive layers 110 and the semiconductor layer 120, respectively.

The conductive layers 110 extend in the X direction, for example, as illustrated in FIG. 3. As illustrated in FIG. 6, each of the conductive layers 110 is, for example, a stacked film including a barrier conductive layer 111 such as titanium nitride (TiN) and a metal film 112 such as tungsten (W). Some of the conductive layers 110 function as the gate electrodes of the word line WL and the memory cell MC (FIG. 1), respectively. At least some of the conductive layers 110, which are provided above the conductive layers 110 functioning as the gate electrodes of the word line WL and the memory cell MC, function as the gate electrodes of the drain side select gate line SGD and the drain side select transistor STD (FIG. 1). As illustrated in FIG. 6, insulating metal oxide layers 113 such as alumina (AlO) covering an upper surface, a lower surface, and a side surface in the Y direction may be provided on the upper surface, the lower surface, and the side surface in the Y direction of the conductive layer 110.

The semiconductor layer 115 (FIG. 4) extends in the X direction. The semiconductor layer 115 is, for example, a semiconductor layer containing polycrystalline silicon (Si) or the like. The semiconductor layer 115 functions as the gate electrodes of the source side select gate line SGS and the source side select transistor STS (FIG. 1).

The semiconductor layer 116 (FIG. 4) extends in the X direction. The semiconductor layer 116 is, for example, a semiconductor layer containing polycrystalline silicon (Si) or the like. The semiconductor layer 116 functions as a part of the source line SL.

In the following description, when focusing on two stacked structures LS adjacent to each other in the Y direction, a plurality of conductive layers 110 included in one of the two stacked structures LS may be referred to as conductive layers 110a (FIG. 3). A plurality of conductive layers 110 provided in the other stacked structure LS may be referred to as conductive layers 110b (FIG. 3). The conductive layer 110a and the conductive layer 110b are electrically independent. Thus, different voltages can be supplied to the conductive layer 110a and the conductive layer 110b. The conductive layers 110a function as the gate electrodes of the memory cells MC provided in the memory string MSa or the gate electrodes of the drain side select transistors STD provided in the memory string MSa. The conductive layers 110b function as the gate electrodes of the memory cells MC provided in the memory string MSb or the gate electrodes of the drain side select transistors STD provided in the memory string MSb.

The semiconductor layer 120 is, for example, a semiconductor layer such as non-doped polycrystalline silicon (Si). The semiconductor layer 120 has a substantially bottomed square tubular shape, and an insulating layer 125 such as silicon oxide (SiO₂) is provided at a central portion thereof. In the following description, in the semiconductor layer 120, a region facing the plurality of conductive layers 110a may be referred to as a first region 120a (FIG. 3), and a region facing the plurality of conductive layers 110b may be referred to as a second region 120b (FIG. 3). The first region 120a functions as the channel regions of the plurality of memory cells MC provided in the memory string MSa (FIG. 1), and the channel regions of the drain side select transistor STD and the source side select transistor STS. The second region 120b functions as the channel regions of the plurality of memory cells MC provided in the memory string MSb (FIG. 1), and the channel regions of the drain side select transistor STD and the source side select transistor STS.

At an upper end of the semiconductor layer 120, for example, as illustrated in FIG. 4, an impurity region 121 containing an N-type impurity such as phosphorus (P) is provided. The impurity region 121 is connected to the bit line BL extending in the Y direction via a bit line contact BLC such as tungsten (W).

A lower end of the semiconductor layer 120 is connected to the semiconductor layer 116 in the illustrated example. In such a case, the semiconductor layer 116 functions as a part of the source line SL (FIG. 1). The semiconductor layer 120 is electrically connected to the control unit CU via the semiconductor layer 116. Such a configuration is merely an example, and the specific configuration may be adjusted as appropriate. For example, the lower end of the semiconductor layer 120 may be connected to a wiring, a semiconductor layer, or the like other than the semiconductor layer 116.

The gate insulating layer 130 includes a tunnel insulating layer 131, a plurality of charge storage layers 132, and a block insulating layer 133, which are provided from the semiconductor layer 120 side to the conductive layer 110 side.

The tunnel insulating layer 131 includes, for example, silicon oxide (SiO₂), silicon oxynitride (SiON), or other insulating layers. As illustrated in FIG. 4, for example, the tunnel insulating layer 131 may extend in the Z direction along an outer peripheral surface of the semiconductor layer 120. The tunnel insulating layer 131 may be a plurality of insulating layers that line up in the Z direction corresponding to the plurality of charge storage layers 132 and are separated from each other.

The plurality of charge storage layers 132 line up in the Z direction corresponding to the plurality of conductive layers 110. Each of the charge storage layers 132 is, for example, a floating gate containing a conductive material. FIG. 6 illustrates a distance between an end surface of the charge storage layer 132 on the conductive layer 110 side in the Y direction and an end surface of the charge storage layer 132 on the semiconductor layer 120 side in the Y direction as a width D11. The width D11 is smaller than 20 nm.

As illustrated in FIG. 6, the charge storage layer 132 may include a narrow portion RN1 and a wide portion RW1 in a YZ cross section. The wide portion RW1 is provided at a position closer to the semiconductor layer 120 than the narrow portion RN1. In FIG. 6, the width of the narrow portion RN1 in the Z direction is illustrated as a width Z11, and the width of the wide portion RW1 in the Z direction is illustrated as a width Z12. Z12 is larger than Z11.

As illustrated in FIGS. 5 and 6, for example, the block insulating layer 133 includes an insulating layer 134, a high dielectric constant layer 135, and an insulating layer 136, which are provided from the semiconductor layer 120 side to the conductive layer 110 side.

The insulating layer 134 is, for example, a stacked film containing silicon oxide (SiO₂) or the like, or titanium nitride (TiN) and silicon oxide (SiO₂). As illustrated in FIG. 5, the insulating layer 134 covers a part of the side surface of the charge storage layer 132 on the conductive layer 110 side in an XY cross section. As illustrated in FIG. 6, the insulating layer 134 covers an upper surface and a lower surface of the narrow portion RN1 and the side surface of the charge storage layer 132 on the conductive layer 110 side in the YZ cross section.

The high dielectric constant layer 135 contains insulating materials such as metal oxides with a relatively high relative permittivity such as hafnium silicate (HfSiO), hafnium oxide (HfO), zirconium oxide (ZrO), yttrium oxide (YO), lanthanum oxide (LaO), or aluminum oxide (AlO). As illustrated in FIG. 5, the high dielectric constant layer 135 covers a part of the side surface of the charge storage layer 132 on the conductive layer 110 side via the insulating layer 134 in the XY cross section. As illustrated in FIG. 6, the high dielectric constant layer 135 covers an upper surface and a lower surface of the insulating layer 134 and a side surface of the insulating layer 134 on the conductive layer 110 side in the YZ cross section.

The insulating layer 136 includes, for example, an insulating layer such as silicon oxide (SiO₂). As illustrated in FIG. 5, the insulating layer 136 covers the side surface of the charge storage layer 132 on the conductive layer 110 side via the high dielectric constant layer 135 in the XY cross section. As illustrated in FIG. 6, the insulating layer 136 covers upper surfaces and lower surfaces of the high dielectric constant layer 135 and the wide portion RW1 in the YZ cross section, and a side surface of the high dielectric constant layer 135 on the conductive layer 110 side.

Writing Operation

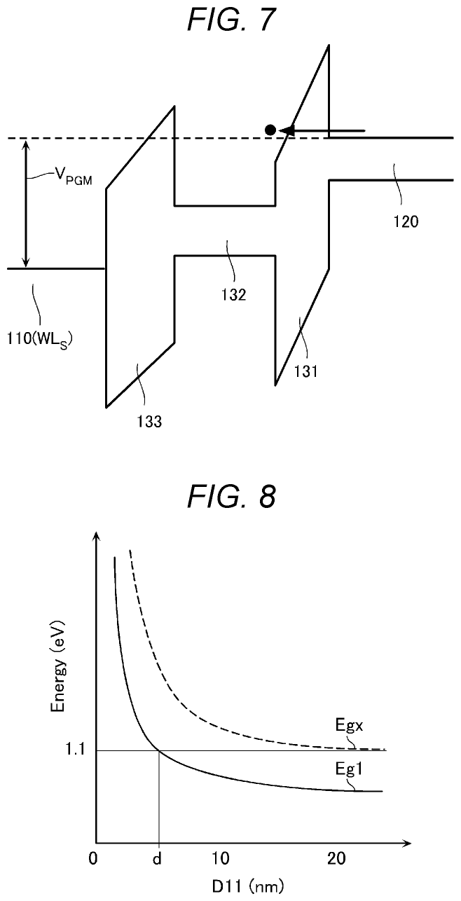

FIG. 7 is a schematic energy band diagram in a writing operation of a configuration near the charge storage layer 132. FIG. 7 illustrates a bandgap energy of a configuration along a dotted line BD1 in FIG. 6. The dotted line BD1 extends in the Y direction through the conductive layer 110, the block insulating layer 133, the charge storage layer 132, the tunnel insulating layer 131, and the semiconductor layer 120. A paper vertical direction in FIG. 7 represents the potential of electrons, and FIG. 7 illustrates that the potential of electrons decreases toward the bottom.

In the writing operation, for example, a ground voltage V_{SS} or a voltage having a magnitude similar to the ground voltage V_{SS} is supplied to the bit line BL, and this voltage is transferred to the semiconductor layer 120. A writing voltage V_{PGM} is supplied to a selected word line WL_{S}. The writing voltage V_{PGM} is greater than the ground voltage V_{SS}. Thus, a relatively large potential difference is generated between the semiconductor layer 120 and the selected word line WL_{S}, and a relatively large electric field is generated in the tunnel insulating layer 131. Accordingly, the effective width of the energy barrier between a conduction band of the tunnel insulating layer 131 and a conduction band of the semiconductor layer 120 becomes smaller, and FN tunneling of electrons occurs. Accordingly, the electrons in the semiconductor layer 120 tunnel into the charge storage layer 132 and are stored in the charge storage layer 132. As a result, the threshold voltage of the memory cell MC increases.

Thinning of Floating Gate

Next, with reference to FIGS. 8 to 10, a phenomenon that occurs with the thinning of the floating gate will be described.

In recent years, high integration of semiconductor storage devices is further being promoted. The high integration is achieved, for example, by thinning the stacked film in the Z direction and miniaturizing a layout design in the XY direction.

In order to reduce the size of the memory cell MC as illustrated in FIG. 5 in the Y direction, for example, it is conceivable to perform the thinning of the charge storage layer 132 that functions as the floating gate. However, when the thinning of the floating gate is promoted, the writing characteristics may be deteriorated. Hereinafter, one cause of such a phenomenon will be described.

FIG. 8 is a schematic graph illustrating a relationship between the film thickness of the floating gate and the bandgap energy. A horizontal axis in FIG. 8 illustrates the width D11 of the floating gate described with reference to FIG. 6, and a vertical axis illustrates the bandgap energy of the floating gate. A dotted line in FIG. 8 illustrates the characteristics when silicon (Si) is used as a material of the charge storage layer 132. A solid line in FIG. 8 illustrates the characteristics when a material having a bandgap energy smaller than that of silicon (Si) is used as the material of the charge storage layer 132.

As illustrated by the dotted line in FIG. 8, when the width D11 is larger than 20 nm, a bandgap energy Egx of the charge storage layer 132 made of silicon (Si) is about 1.1 eV. 1.1 eV is about the same as the bandgap energy of bulk silicon (Si). When the width D11 is smaller than 20 nm, the bandgap energy Egx of the charge storage layer 132 made of silicon (Si) increases as the width D11 becomes smaller. The increase in the bandgap energy Egx is caused by a remarkable development of the quantum effect by thinning the charge storage layer 132.

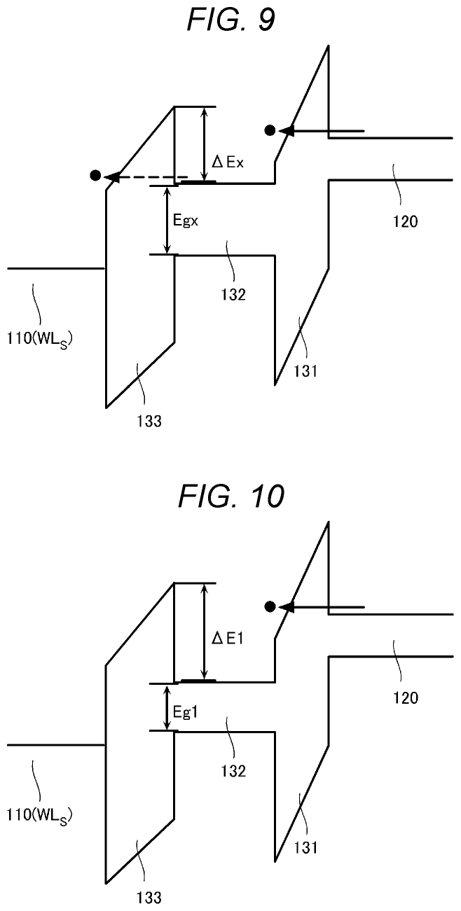

FIG. 9 is a schematic energy band diagram in a writing operation of a configuration near the charge storage layer 132. FIG. 9 illustrates a bandgap energy of a configuration along the dotted line BD1 in FIG. 6. A paper vertical direction in FIG. 9 represents the potential of electrons, and FIG. 9 illustrates that the potential of electrons decreases toward the bottom.

FIG. 9 illustrates a state in which silicon (Si) is used as the material of the charge storage layer 132.

For example, when the width D11 of the charge storage layer 132 is made smaller than 20 nm, the bandgap energy Egx of the charge storage layer 132 made of silicon becomes larger than 1.1 eV (FIG. 8). In such a case, as illustrated in FIG. 9, an energy gap AEx between a conduction band of the charge storage layer 132 and a conduction band of the block insulating layer 133 becomes relatively small. If a large voltage is applied to the block insulating layer 133 in such a state, the effective width of the energy barrier between the conduction band of the block insulating layer 133 and the conduction band of the charge storage layer 132 becomes small, and the FN tunneling of electrons may occur. Accordingly, the electrons in the charge storage layer 132 may escape to the conductive layer 110, making it difficult to suitably raise the threshold voltage of the memory cell MC.

Thus, in the embodiment, as the material of the charge storage layer 132, a material having a bandgap energy Eg1 lower than the bandgap energy of silicon (Si) is used.

Here, as illustrated by the solid line in FIG. 8, when the width D11 is larger than 20 nm, the bandgap energy Eg1 of the charge storage layer 132 containing the above material is smaller than 1.1 eV. When the width D11 is smaller than 20 nm, the bandgap energy Eg1 of the charge storage layer 132 containing the above material increases as the width D11 becomes smaller due to the quantum effect described above. However, by using the above material, it is possible to reduce the bandgap energy Eg1 to 1.1 eV or less even when the charge storage layer 132 is thinned to 20 nm or less. For example, in the example of FIG. 8, even when the width D11 is thinned to about 5 nm, the bandgap energy Eg1 can be reduced to about 1.1 eV.

FIG. 10 is a schematic energy band diagram in a writing operation of a configuration near the charge storage layer 132. FIG. 10 illustrates a bandgap energy of a configuration along the dotted line BD1 in FIG. 6. A paper vertical direction in FIG. 10 represents the potential of electrons, and FIG. 10 illustrates that the potential of electrons decreases toward the bottom.

FIG. 10 illustrates the state in which the material having the bandgap energy Eg1 lower than the bandgap energy of silicon (Si) is used as the material of the charge storage layer 132.

For example, when the width D11 of the charge storage layer 132 is about 5 nm to 20 nm, the bandgap energy Eg1 of the charge storage layer 132 including the above material is smaller than 1.1 eV (FIG. 8). In such a case, as illustrated in FIG. 10, an energy gap ΔE1 between the charge storage layer 132 and the block insulating layer 133 can be made relatively large. Accordingly, it is possible to reduce the occurrence of the FN tunneling of electrons as described above. As a result, it is possible to prevent the electrons in the charge storage layer 132 from escaping to the conductive layer 110.

As a result, in the semiconductor storage device according to the embodiment, even when the floating gate is thinned, it is possible to achieve the high integration of the memory cell MC while reducing deterioration of the writing characteristics.

Material of Charge Storage Layer 132

Next, as the material of the charge storage layer 132, a material having the bandgap energy Eg1 lower than the bandgap energy of silicon (Si) as described above will be described.

The charge storage layer 132 contains silicon (Si) and at least one of germanium (Ge), tin (Sn), magnesium (Mg), or carbon (C). The charge storage layer 132 may be a mixed crystal of silicon (Si) and at least one of germanium (Ge), tin (Sn), magnesium (Mg), or carbon (C). A mixed crystal of silicon (Si) and at least one of germanium (Ge), tin (Sn), magnesium (Mg), or carbon (C) has a lower bandgap energy than silicon (Si), as described below.

The charge storage layer 132 may include, for example, a polycrystal or a single crystal containing silicon (Si) and germanium (Ge) as constituent atoms. Hereinafter, a composition of the crystal containing silicon (Si) and germanium (Ge) is described as Si₁₋ₓGeₓ (x is a value from 0 to 1), and an example in which the bandgap energy changes with respect to the composition will be given.

For example, the bandgap energy of bulk S₁₋ₓGₓ is about 1.1 eV, which is close to the bandgap energy of the bulk silicon (Si) when x is close to 0. In the case of bulk Si_{0.4}Ge_{0.6} in which a composition ratio of germanium (Ge) is increased to about x=0.6, the bandgap energy is reduced to about 1.0 eV. As described above, in S₁₋ₓGₓ, the bandgap energy decreases as the composition ratio of germanium (Ge) increases.

Further, in the composition of S₁₋ₓGₓ, when the charge storage layer 132 is formed, for example, with the width d (FIG. 8), x may be selected so that the bandgap energy is the same as 1.1 eV, which is the same as the bandgap energy of the bulk silicon (Si), or close to 1.1 eV, due to the quantum effect of thinning.

The charge storage layer 132 may include, for example, a polycrystal or a single crystal containing silicon (Si) and tin (Sn) as constituent atoms. Hereinafter, a composition of the crystal containing silicon (Si) and tin (Sn) is described as Si_{1-y}Sn_{y} (y is a value from 0 to 1), and an example in which the bandgap energy changes with respect to the composition will be given.

For example, the bandgap energy of bulk Si_{1-y}Sn_{y} is about 1.1 eV when y is close to 0. In the case of bulk Si_{0.5}Sn_{0.5} in which a composition ratio of tin (Sn) is increased to about y=0.5, the bandgap energy is reduced to about 1.0 eV. As described above, in Si_{1-y}Sn_{y}, the bandgap energy decreases as the composition ratio of tin (Sn) increases.

Further, in the composition of Si_{1-y}Sn_{y}, when the charge storage layer 132 is formed with one width d (FIG. 8), y may be selected so that the bandgap energy is the same as 1.1 eV, which is the same as the bandgap energy of the bulk silicon (Si), or close to 1.1 eV, due to the quantum effect of thinning.

The charge storage layer 132 may include, for example, a polycrystal or a single crystal containing silicon (Si), magnesium (Mg) and carbon (C) as constituent atoms. Hereinafter, a composition of the crystal containing silicon (Si), magnesium (Mg), and carbon (C) is described as Mg₂Si_{1-z}C_{z} (z is a value from 0 to 1), and an example in which the bandgap energy changes with respect to the composition will be given.

For example, the bandgap energy of bulk Mg₂Si_{1-z}C_{z} is about 0.9 eV when z is close to 1. When a composition ratio of silicon (Si) is increased to about z=0, the bandgap energy is reduced to about 0.3 eV. As described above, in Mg₂Si_{1-z}C_{z}, the bandgap energy decreases as the composition ratio of silicon (Si) to carbon (C) increases.

Further, in the composition of Mg₂Si_{1-z}C_{z}, when the charge storage layer 132 is formed with one width d (FIG. 8), z may be selected so that the bandgap energy becomes a value close to 1.1 eV, due to the quantum effect of thinning.

The charge storage layer 132 may contain, for example, N-type impurities such as phosphorus (P) or P-type impurities such as boron (B), in addition to silicon (Si), germanium (Ge), tin (Sn), magnesium (Mg), and carbon (C).

Concentration of silicon (Si), germanium (Ge), tin (Sn), magnesium (Mg), carbon (C), and the like in the material contained in the charge storage layer 132 can be measured by an energy dispersive X-ray spectrometer (EDS) or the like.

A crystal structure of the material contained in the charge storage layer 132 in a nanometer region can be measured by nano beam electron diffraction (NBD) or the like.

The band gap of the material contained in the charge storage layer 132 can be analyzed by a method such as light absorption spectrum measurement.

Manufacturing Method

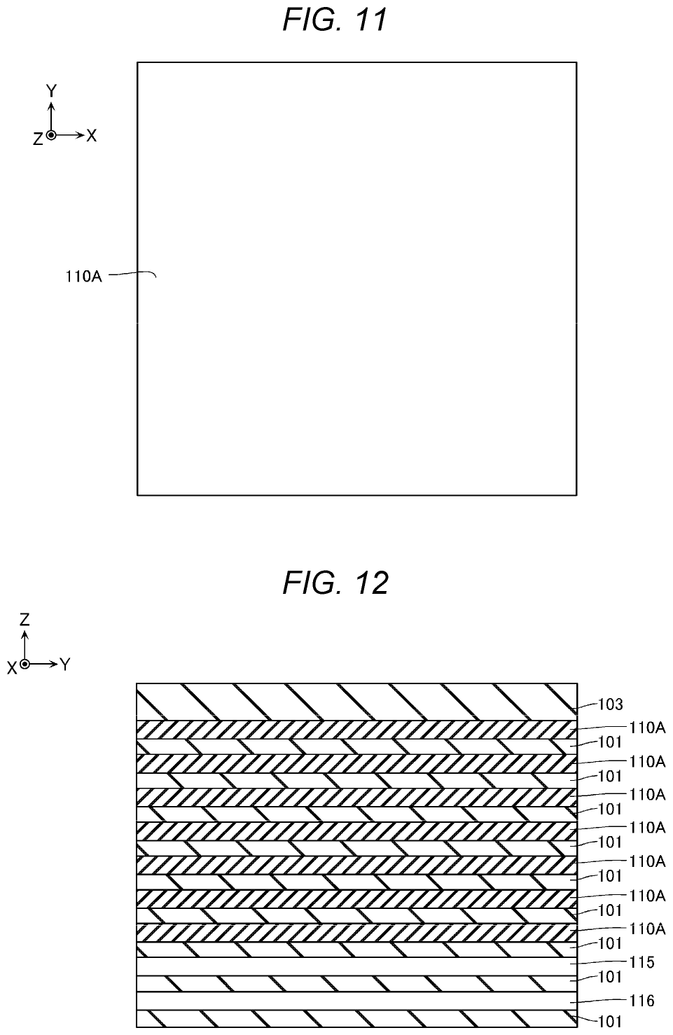

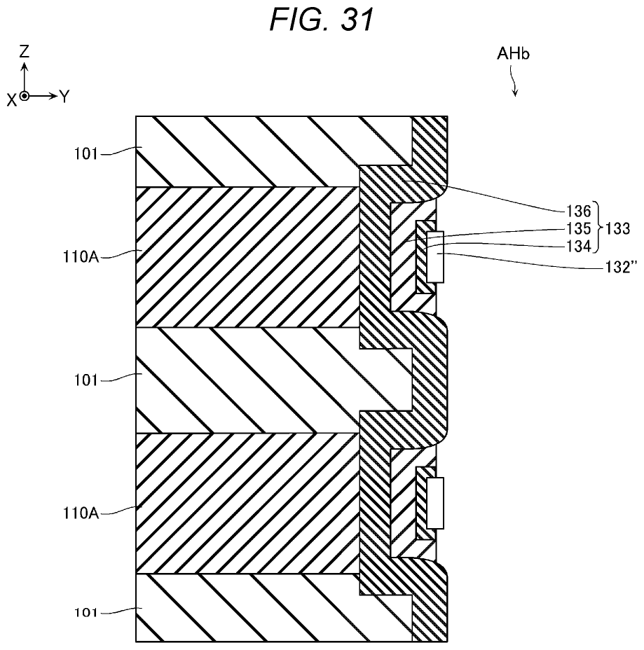

Next, a manufacturing method for the semiconductor storage device according to the embodiment will be described with reference to FIGS. 11 to 37. FIGS. 11, 13, 15, 17, 19, 21, 23, 25, and 27 are schematic XY cross-sectional views illustrating the manufacturing method, and correspond to a portion illustrated in FIG. 3. FIGS. 12, 14, 16, 18, 20, 22, 24, 26, 28, 35 and 36 are schematic YZ cross-sectional views illustrating the manufacturing method, and correspond to a portion illustrated in FIG. 4. FIGS. 29 to 34 and 37 are schematic cross-sectional views illustrating the manufacturing method, and correspond to a portion illustrated in FIG. 6.

As illustrated in FIGS. 11 and 12, in the same manufacturing method, the plurality of insulating layers 101, the semiconductor layer 116, the semiconductor layer 115, and sacrifice layers 110A are alternately stacked on the semiconductor substrate 100 (not illustrated), and an insulating layer 103 is formed on the stacked layers. Each of the sacrifice layers 110A is made of, for example, silicon nitride (SiN) or the like. The insulating layer 103 is made of, for example, silicon oxide (SiO₂) or the like. This step is performed by a method such as chemical vapor deposition (CVD).

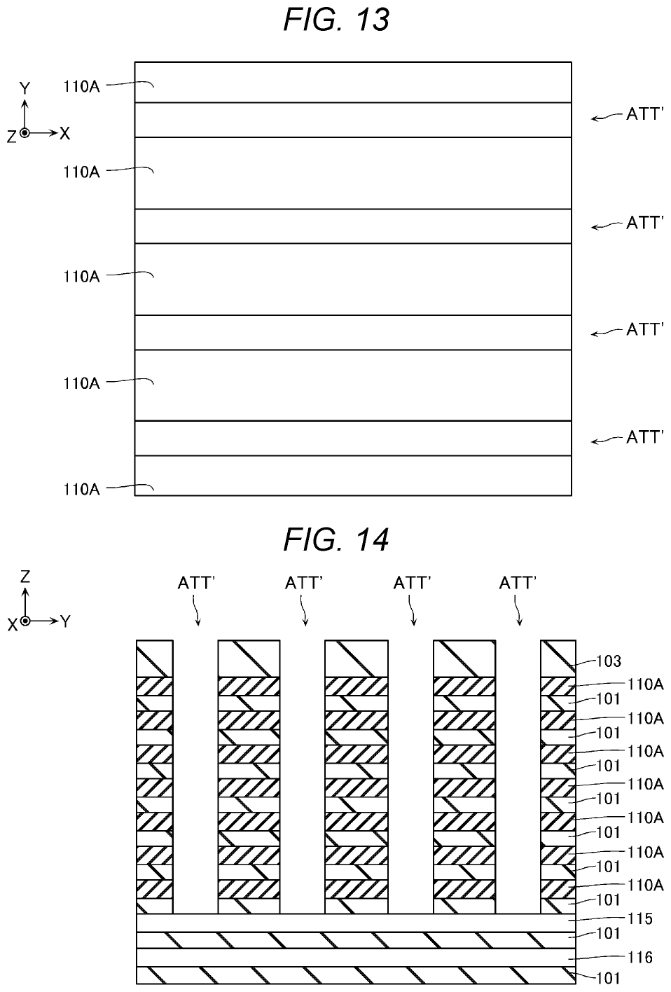

Next, as illustrated in FIGS. 13 and 14, trenches ATT′ are formed in the stacked structure including the insulating layer 103, the insulating layers 101, and the sacrifice layers 110A. In this step, for example, an insulating layer having openings in portions corresponding to the trenches ATT′ is formed on the upper surface of the structure illustrated in FIG. 12, and reactive ion etching (RIE) or the like is performed using this insulating layer as a mask. As illustrated in FIG. 13, the trenches ATT′ extend in the X direction. As illustrated in FIG. 14, the trenches ATT′ extend in the Z direction, penetrate the insulating layer 103, the plurality of insulating layers 101, and the plurality of sacrifice layers 110A, and divide these configurations in the Y direction.

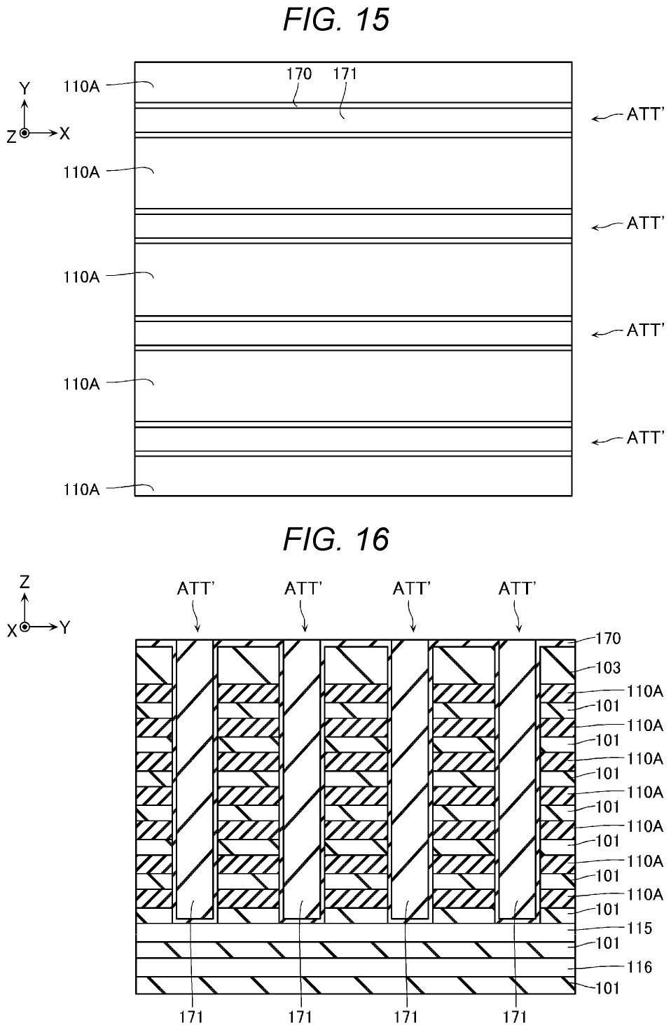

Next, as illustrated in FIGS. 15 and 16, an insulating layer 170 is formed on an upper surface of the insulating layer 103 and on bottom surfaces and side surfaces of the trenches ATT′. The insulating layer 170 is made of, for example, silicon oxide (SiO₂) or the like. The step is performed by, for example, a method such as CVD. A carbon film 171 embedding the trench ATT′ is formed on an upper surface of the insulating layer 170. The carbon film 171 is formed by, for example, spin coating of a coated carbon material. Further, an upper portion of the carbon film 171 is removed up to the same position as the upper surface of the insulating layer 170. The removal of the carbon film 171 is performed by, for example, RIE or the like.

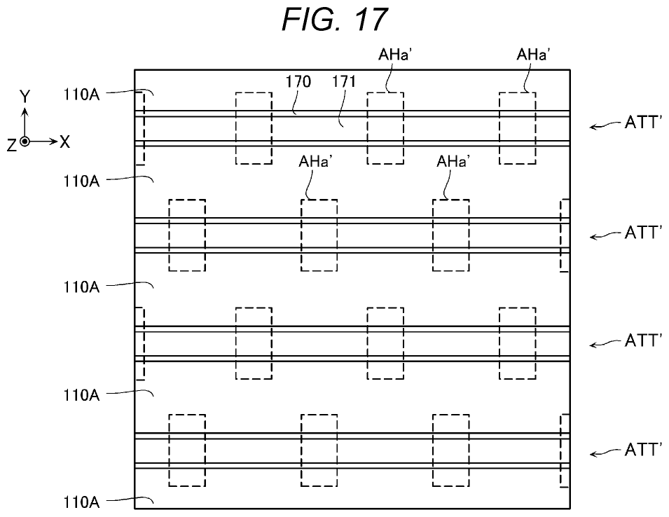

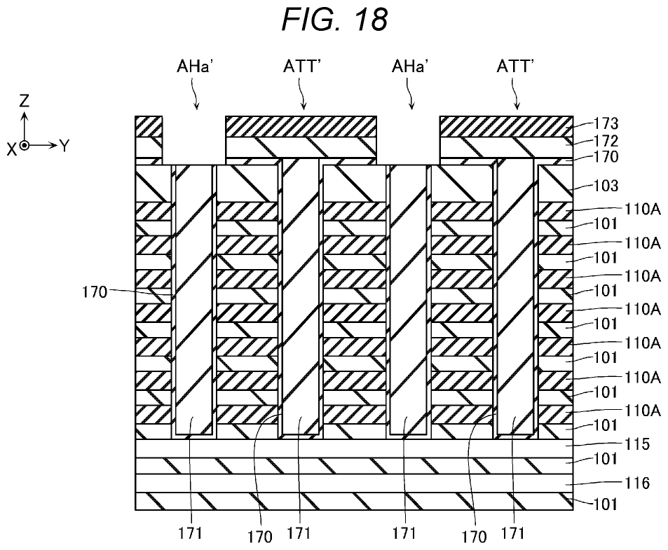

Next, as illustrated in FIGS. 17 and 18, a hard mask 172 and a resist 173 are formed on the upper surface of the structure illustrated in FIG. 16. The hard mask 172 is made of, for example, silicon oxide (SiO₂) or the like. The hard mask 172 is formed, for example, by CVD or the like. The resist 173 is formed by spin coating or the like of a resist material. Using the resist 173 as a mask, openings AHa′ are formed. The openings AHa′ penetrate the hard mask 172 and the insulating layer 170 to expose the carbon films 171. The opening AHa′ is formed, for example, by a method such as photolithography and RIE.

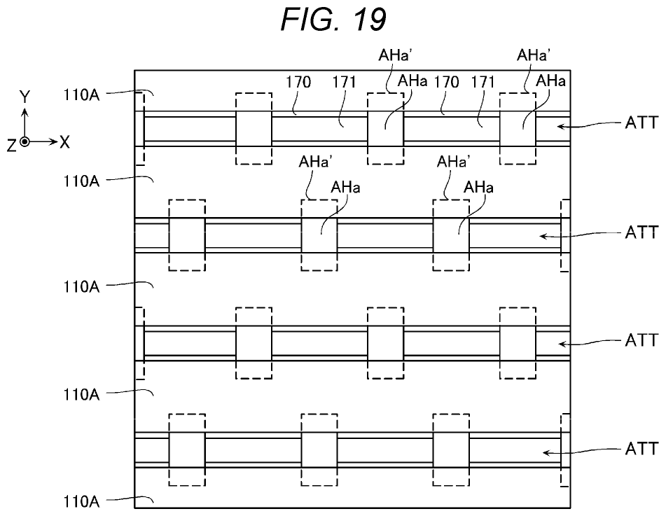

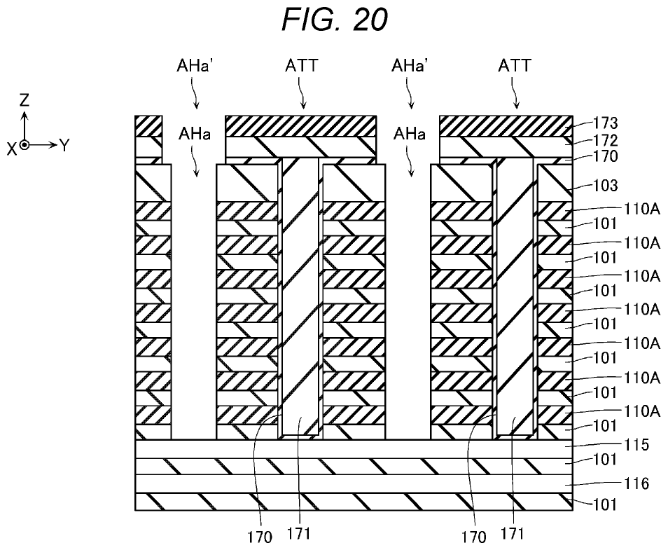

Next, as illustrated in FIGS. 19 and 20, portions of the carbon film 171 and the insulating layer 170 provided at the position corresponding to the opening AHa′ are removed to form an opening AHa. The step of removing the carbon film 171 is performed by, for example, ashing or the like. The step of removing the insulating layer 170 is performed by, for example, chemical dry etching or the like. Hereinafter, a plurality of portions of the trench ATT′ divided by a plurality of openings AHa lining up in the X direction are referred to as trenches ATT, respectively.

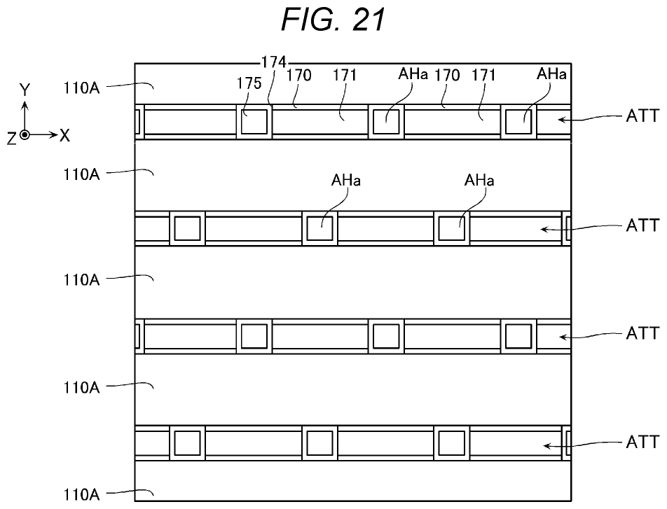

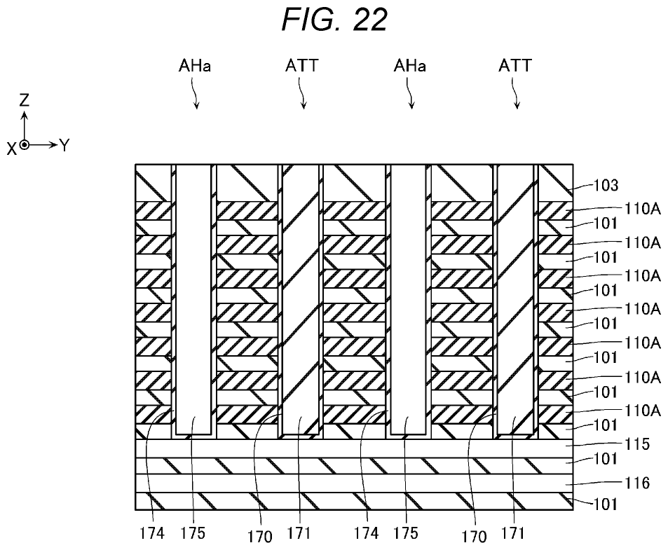

Next, as illustrated in FIGS. 21 and 22, the resist 173, the hard mask 172, and the insulating layer 170 are removed from an upper surface of the structure illustrated in FIG. 20. This step is performed by, for example, ashing, RIE, or the like.

An insulating layer 174 such as silicon oxide (SiO₂) is formed on a bottom surface and side surfaces of each of the openings AHa. A semiconductor layer 175 such as amorphous silicon (Si) in which the opening AHa is embedded is formed on an upper surface of the insulating layer 174. The insulating layer 174 and the semiconductor layer 175 are formed by a method such as CVD. Upper portions of the insulating layer 174 and the semiconductor layer 175 are removed up to the same positions as the upper surface of the insulating layer 103. The insulating layer 174 and the semiconductor layer 175 are removed by, for example, RIE.

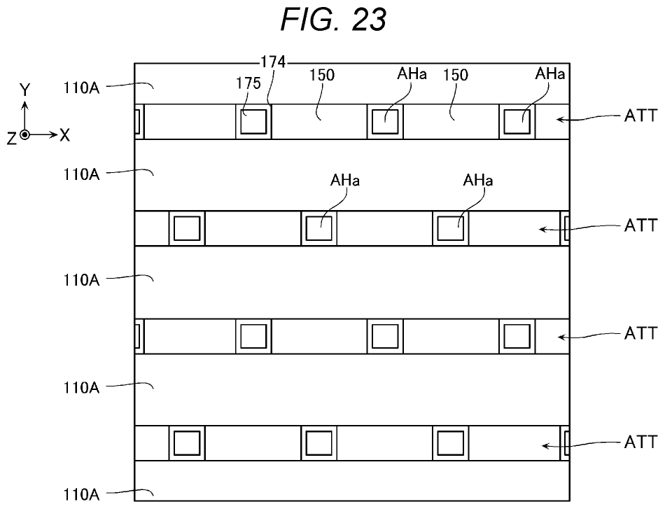

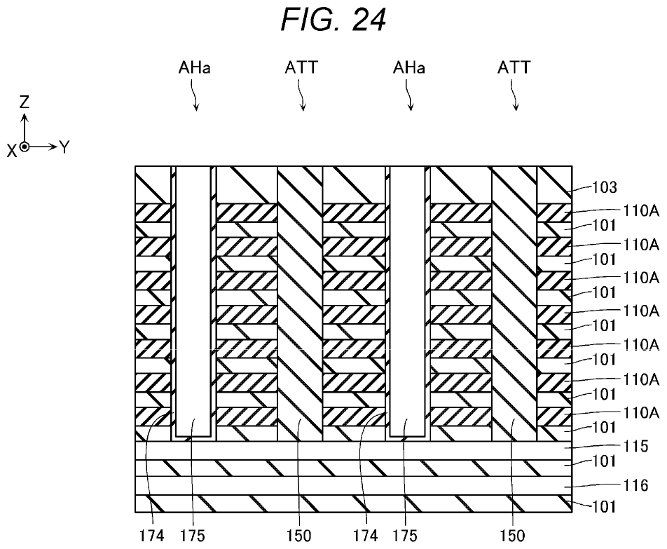

Next, as illustrated in FIGS. 23 and 24, the carbon film 171 and the insulating layer 170 are removed from the inside of each of the trenches ATT. This step is performed by, for example, asking, RIE, or the like. The insulating layer 150 is formed in the trench ATT, and the upper surface of the insulating layer 150 is removed up to the position of the upper surface of the insulating layer 103. This step is performed by, for example, CVD, RIE, or the like.

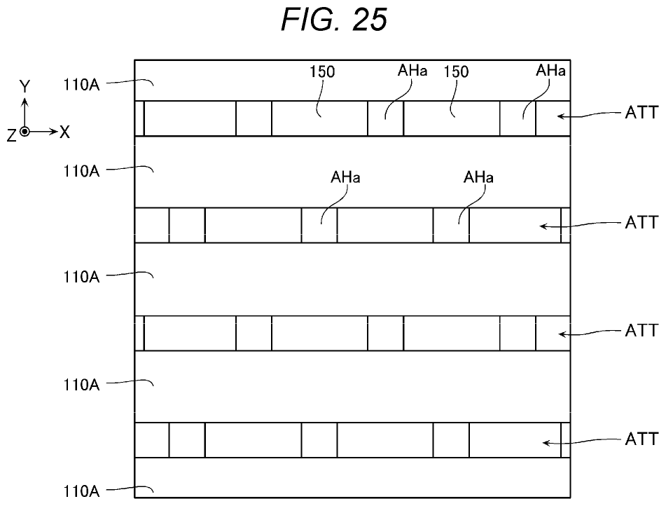

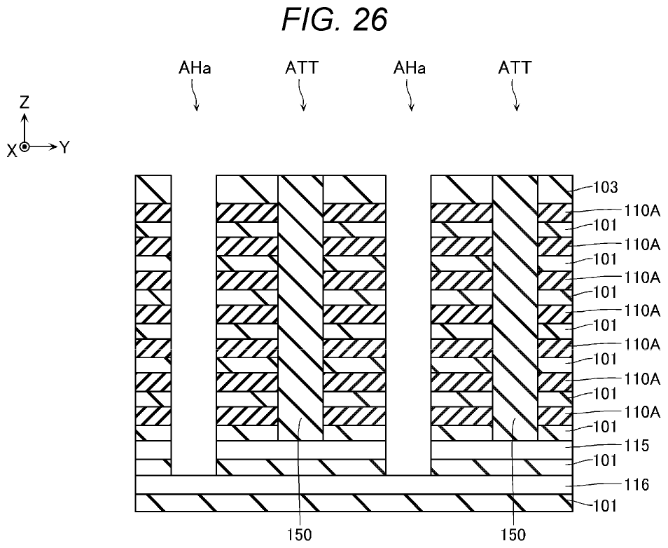

Next, as illustrated in FIGS. 25 and 26, the semiconductor layer 175 is removed from the inside of each of the openings AHa. The step is performed by a method such as wet etching. The insulating layer 174 is removed from the inside of each of the openings AHa, and a bottom portion of the opening AHa is further removed until the position of the bottom surface of the opening AHa coincides with the position of the upper surface of the semiconductor layer 116. This step is performed by, for example, RIE, or the like.

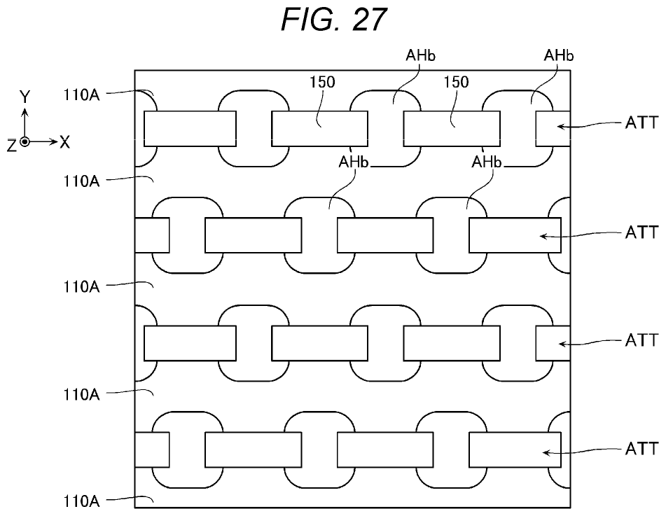

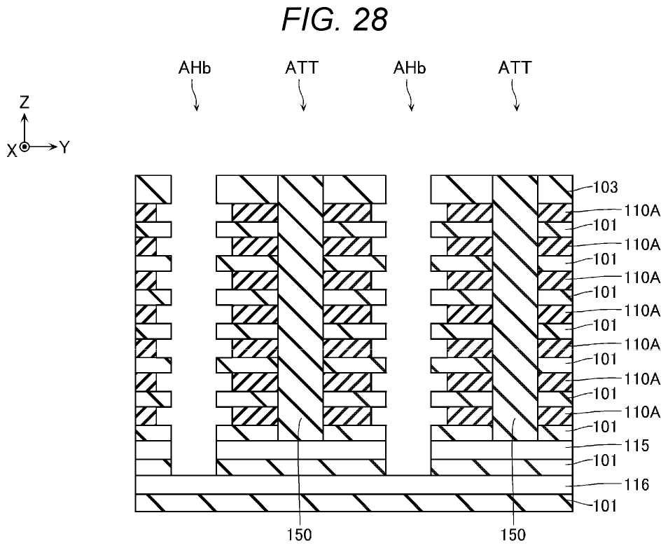

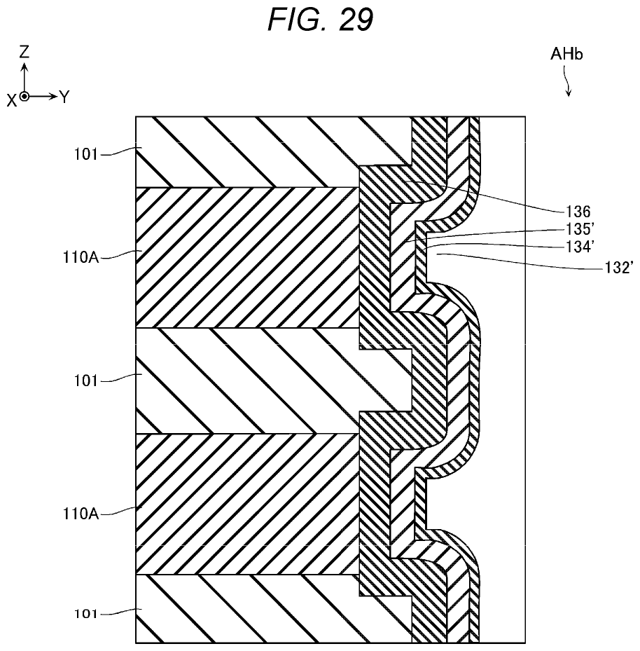

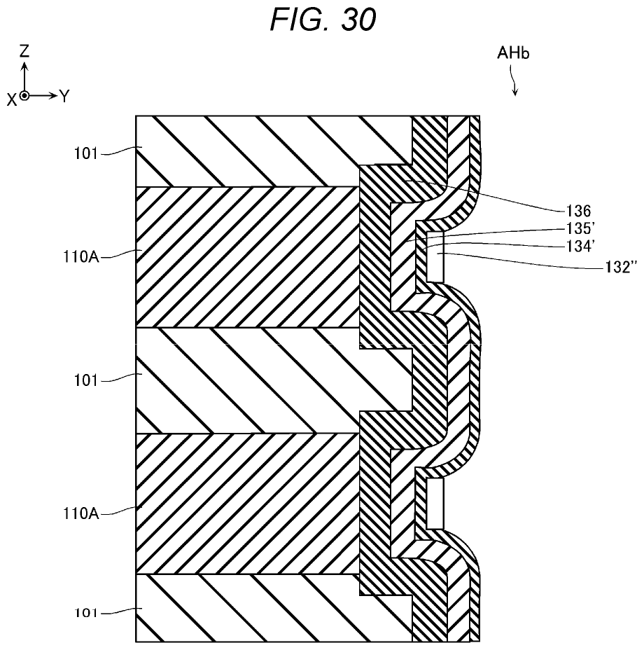

Next, as illustrated in FIGS. 27 and 28, portions of the sacrifice layers 110A are removed through each of the openings AHa to form an opening AHb. By this step, portions of the upper surface and the lower surface of the insulating layer 101, which are located in the vicinity of the opening AHa are exposed. The step is performed by a method such as wet etching.

Next, as illustrated in FIG. 29, the insulating layer 136, a high dielectric constant layer 135′, an insulating layer 134′, and a semiconductor layer 132′ are sequentially formed on the side surface of the opening AHb via the opening AHb. The high dielectric constant layer 135′ is, for example, an insulating metal oxide layer such as hafnium silicate (HfSiO). The insulating layer 134′ is, for example, a stacked film containing silicon oxide (SiO₂) or the like, or titanium nitride (TiN) and silicon oxide (SiO₂).

The semiconductor layer 132′ is, for example, a polycrystal containing silicon (Si) and at least one of germanium (Ge), tin (Sn), magnesium (Mg), and carbon (C). The step is performed by, for example, CVD or the like.

Next, as illustrated in FIG. 30, parts of the semiconductor layer 132′ are removed to form a plurality of semiconductor layers 132″ lining up in the Z direction corresponding to the sacrifice layers 110A. The step is performed by a method such as wet etching.

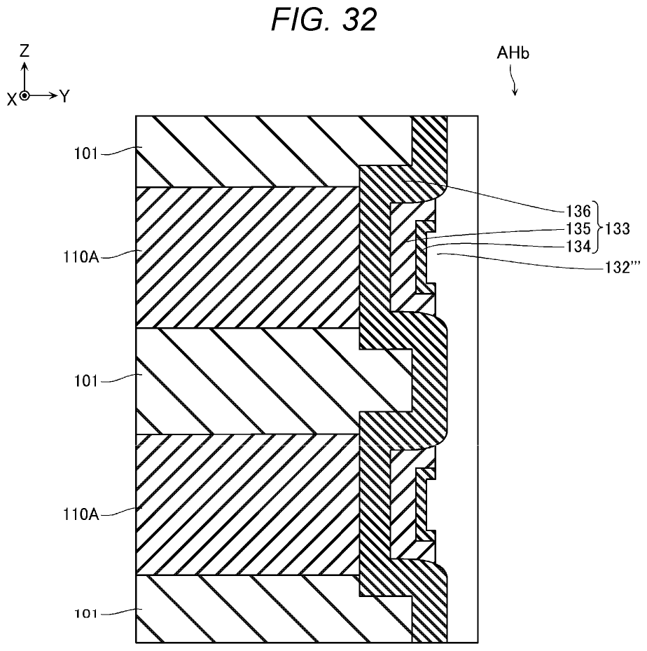

Next, as illustrated in FIG. 31, parts of the high dielectric constant layer 135′ and the insulating layer 134′ are removed, and the plurality of high dielectric constant layers 135 and the insulating layer 134 lining up in the Z direction are formed corresponding to the sacrifice layers 110A. End surfaces of the high dielectric constant layer 135 and the insulating layer 134 on the opening AHb side are closer to the sacrifice layer 110A than an end surface of the semiconductor layer 132″ on the opening AHb side. The step is performed by a method such as wet etching.

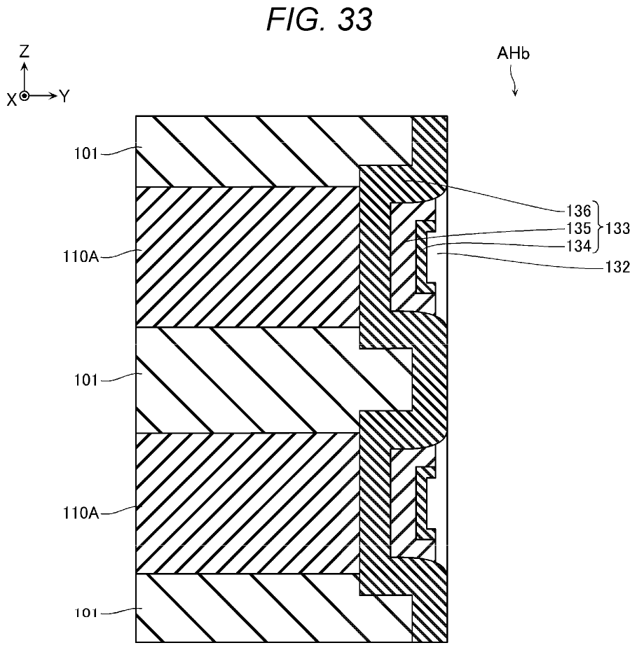

Next, as illustrated in FIG. 32, the same material as the semiconductor layer 132″ is formed through the opening AHb to form a semiconductor layer 132′″. The step is performed by, for example, CVD or the like.

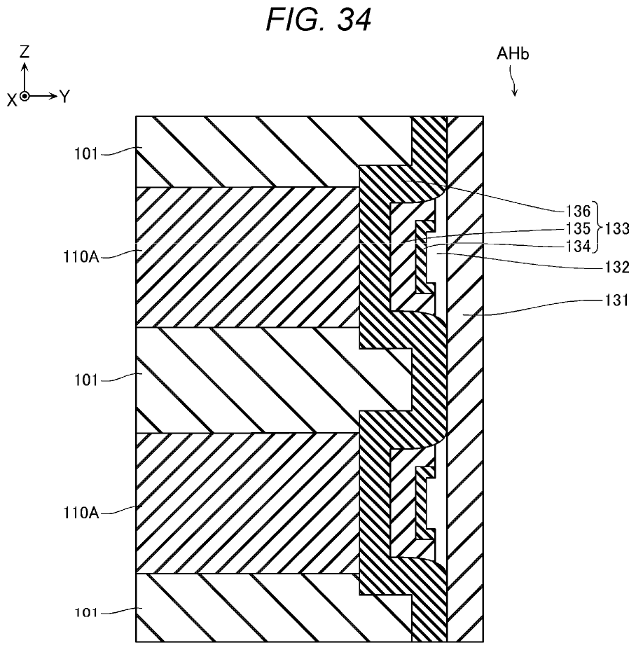

Next, as illustrated in FIG. 33, a part of the semiconductor layer 132′″ is removed through the opening AHb to form the plurality of charge storage layers 132 lining up in the Z direction corresponding to the sacrifice layers 110A. The step is performed by a method such as wet etching.

Next, as illustrated in FIG. 34, the tunnel insulating layer 131 is formed on an inner peripheral surface of the opening AHb. This step is performed, for example, by CVD, oxidation treatment, or the like. When the tunnel insulating layer 131 is formed by a method such as CVD, the tunnel insulating layer 131 extends in the Z direction along the inner peripheral surface of the opening AHb. When the tunnel insulating layer 131 is formed by a method such as an oxidation treatment, the tunnel insulating layer 131 is formed on a side surface in the Y direction of the charge storage layer 132.

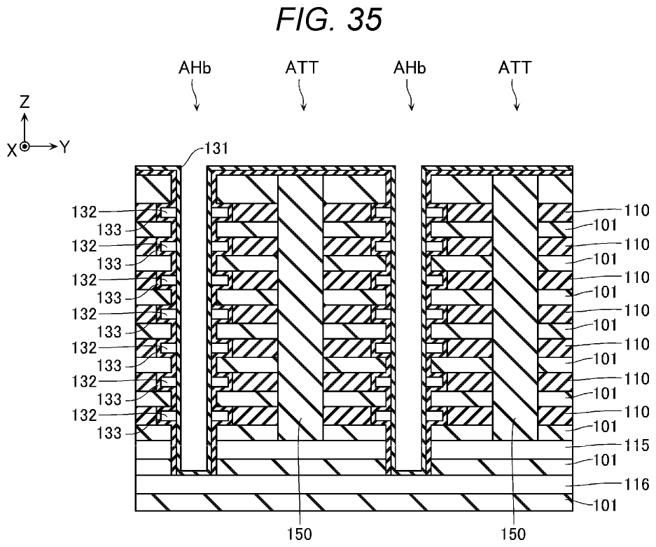

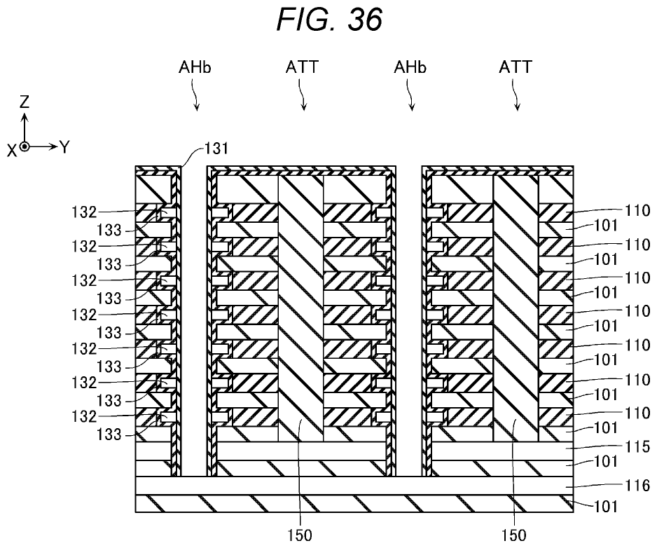

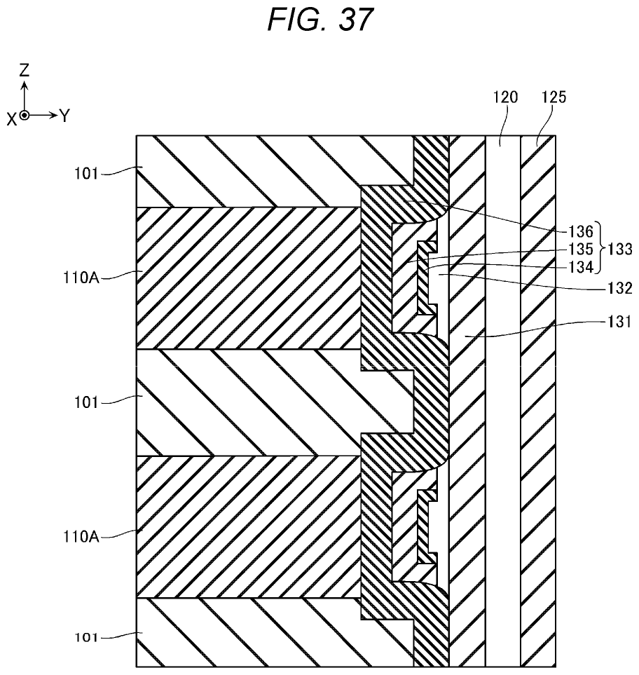

Next, as illustrated in FIGS. 35 and 36, a portion of the tunnel insulating layer 131 that covers the bottom surface of the opening AHb is removed. This step is performed by, for example, RIE, or the like.

Next, as illustrated in FIG. 37, the semiconductor layer 120 and the insulating layer 125 are formed in the opening AHb. The step is performed by, for example, CVD or the like.

Next, the plurality of sacrifice layers 110A are removed through openings (not illustrated). The step is performed by a method such as wet etching.

Next, as illustrated in FIG. 6, the metal oxide layers 113 are formed on the upper surface and the lower surface of the insulating layer 101 and the side surface in the Y direction of the insulating layer 136 through the openings (not illustrated). The conductive layers 110 are respectively formed so as to fill cavities formed by removing the plurality of sacrifice layers 110A. The step is performed by, for example, CVD or the like.

Next, the semiconductor storage device according to the first embodiment is manufactured by forming the bit line contact BLC, the bit line BL, and the like.

### Another Embodiment

The semiconductor storage device according to the first embodiment was illustrated above. However, the above aspects are merely examples, and specific aspects and the like may be appropriately adjusted.

For example, in the semiconductor storage device described with reference to FIGS. 3 to 6, the plurality of conductive layers 110a lining up in the Z direction and extending in the X direction and the plurality of conductive layers 110b extending in the X direction apart from the plurality of conductive layers 110a in the Y direction function as the word lines WL of the memory cells MC, respectively. The first region 120a and the second region 120b (FIG. 3) of the semiconductor layer 120 function as a channel region of the memory cell MC respectively. The charge storage layers 132 are separated in the Y direction between the conductive layer 110a and the semiconductor layer 120 and between the conductive layer 110b and the semiconductor layer 120 in the XY cross section as illustrated in FIG. 5.

However, such a method is merely an example, and the specific structure of the memory cell MC may be appropriately adjusted. For example, a plurality of conductive layers lining up in the Z direction function as the word lines WL of the memory cells MC, the semiconductor layers extending in the Z direction and facing the plurality of conductive layers function as the channel regions of the memory cells MC, and gate insulating layers including a charge storage layer may be provided between the plurality of conductive layers and the semiconductor layers, respectively. In such a configuration, the charge storage layers facing one semiconductor layer in the XY cross section may be connected without being separated in the Y direction, unlike the charge storage layers 132. In such a configuration, the conductive layers facing one semiconductor layer in the XY cross section may be connected without being separated in the Y direction, unlike the conductive layers 110.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a substrate;
a plurality of first conductive layers arranged in a first direction intersecting the substrate and extending in a second direction intersecting the first direction;
a semiconductor layer extending in the first direction and disposed adjacent the plurality of first conductive layers; and
a plurality of first charge storage layers arranged in the first direction, each of the first charge storage layers provided between a corresponding one of the plurality of first conductive layers and the semiconductor layer, wherein
each of the first charge storage layers includes silicon (Si) and at least one of germanium (Ge), tin (Sn), magnesium (Mg), or carbon (C).

2. The semiconductor storage device according to claim 1, comprising:
a plurality of second conductive layers arranged in the first direction, separated from the plurality of first conductive layers in a third direction intersecting the first direction and the second direction, extending in the second direction, and also disposed adjacent the semiconductor layer; and
a plurality of second charge storage layers arranged in the first direction, each of the second charge storage layers provided between a corresponding one of the plurality of second conductive layers and the semiconductor layer.

3. The semiconductor storage device according to claim 1, wherein
the first charge storage layer includes a polycrystal containing silicon (Si) and germanium (Ge) as constituent atoms.

4. The semiconductor storage device according to claim 1, wherein
the first charge storage layer includes a polycrystal containing silicon (Si) and tin (Sn) as constituent atoms.

5. The semiconductor storage device according to claim 1, wherein
the first charge storage layer includes a polycrystal containing silicon (Si) and magnesium (Mg) as constituent atoms.

6. The semiconductor storage device according to claim 1, wherein
the first charge storage layer includes a polycrystal containing silicon (Si), magnesium (Mg), and carbon (C) as constituent atoms.

7. The semiconductor storage device according to claim 2, wherein
a width of the first charge storage layer in the third direction is smaller than about 20 nm.

8. The semiconductor storage device according to claim 1, wherein each of the first charge storage layers includes a first portion disposed closer to the corresponding conductive layer and a second portion disposed closer to the semiconductor layer, and wherein the first portion has a first width extending in the first direction and the second, different width extending in the first direction.

9. The semiconductor storage device according to claim 8, wherein the second width is greater than the first width.

10. A semiconductor storage device, comprising:
a plurality of first conductive layers spaced apart from one another in a vertical direction, each of the first conductive layers extending in a first lateral direction;
a plurality of second conductive layers spaced apart from one another in the vertical direction, each of the second conductive layers also extending in the first lateral direction;
a first semiconductor layer extending in the first direction and interposed between the plurality of first conductive layers and the plurality of second conductive layers along a second lateral direction;
a plurality of first charge storage layers spaced apart from one another in the first direction, each of the first charge storage layers provided between a corresponding one of the plurality of first conductive layers and the first semiconductor layer; and
a plurality of second charge storage layers spaced apart from one another in the first direction, each of the second charge storage layers provided between a corresponding one of the plurality of second conductive layers and the first semiconductor layer, wherein
each of the first and second charge storage layers includes silicon (Si) and at least one of germanium (Ge), tin (Sn), magnesium (Mg), or carbon (C).

11. The semiconductor storage device according to claim 10, further comprising:
a second semiconductor layer extending in the first direction, interposed between the plurality of first conductive layers and the plurality of second conductive layers along the second lateral direction, and spaced apart from the first semiconductor layer in the first lateral direction;
a plurality of third charge storage layers spaced apart from one another in the first direction, each of the third charge storage layers provided between a corresponding one of the plurality of first conductive layers and the second semiconductor layer; and
a plurality of fourth charge storage layers spaced apart from one another in the first direction, each of the fourth charge storage layers provided between a corresponding one of the plurality of second conductive layers and the second semiconductor layer, wherein
each of the third and fourth charge storage layers includes silicon (Si) and at least one of germanium (Ge), tin (Sn), magnesium (Mg), or carbon (C).

12. The semiconductor storage device according to claim 10, wherein
the first and second charge storage layers each include a polycrystal containing silicon (Si) and germanium (Ge) as constituent atoms.

13. The semiconductor storage device according to claim 10, wherein
the first and second charge storage layers each include a polycrystal containing silicon (Si) and tin (Sn) as constituent atoms.

14. The semiconductor storage device according to claim 10, wherein
the first and second charge storage layers each include a polycrystal containing silicon (Si) and magnesium (Mg) as constituent atoms.
